(19) United States
(12) Patent Application Publication
(10) Pub. No.: US 2018/0069173 A1
(43) Pub. Date: Mar. 8, 2018

(54) MAGNETIC TUNNEL JUNCTION DEVICE

(71) Applicants: Yoshiaki SONOBE, Yokohama (JP); Shigeki NAKAGAWA, Tokyo (JP)

(72) Inventors: Yoshiaki SONOBE, Yokohama (JP); Shigeki NAKAGAWA, Tokyo (JP)

(21) Appl. No.: 15/681,319

(22) Filed: Aug. 18, 2017

(30) Foreign Application Priority Data
Sep. 2, 2016 (JP) 2016-172032

(51) Int. Cl. H01L 43/10; H01L 43/08; H01L 27/22

(52) U.S. Cl. CPC H01L 43/10; H01L 27/222; H01L 43/08

(57) ABSTRACT

A free layer has a switchable magnetization direction. A reference layer has a fixed magnetization direction. A barrier layer is provided between the free layer and the reference layer. The free layer includes a perpendicularity-maintaining layer and a high-polarizability magnetic layer. The perpendicularity-maintaining layer, if in contact with the barrier layer, has a first surface roughness. The high-polarizability magnetic layer, if in contact with the barrier layer, has a second surface roughness. If the first surface roughness is smaller than the second surface roughness, the perpendicularity-maintaining layer is in contact with the barrier layer. If the second surface roughness is smaller than the first surface roughness, the high-polarizability magnetic layer is in contact with the barrier layer.

### CROSS-REFERENCE TO RELATED APPLICATION

This application claims priority under 35 U.S.C. §119 to Japanese Patent Application No. 2016-172032, filed on Sep. 2, 2016, in the Japanese Intellectual Property Office, the disclosure of which is incorporated by reference herein in its entirety.

### TECHNICAL FIELD

The present inventive concept relates to a magnetic tunnel junction device.

### DESCRIPTION OF RELATED ART

Ferromagnetic materials having a high perpendicular magnetic anisotropy and a high spin polarizability are used constituent materials of magnetic tunnel junctions. Such ferromagnetic materials are extremely rare. Composite layers have been proposed for the ferromagnetic materials in the following documents, for example: JP2014-116474 A; and JP2016-092066.

### SUMMARY

According to an exemplary embodiment of the present inventive concept, a magnetic tunnel junction device includes as follows. A free layer has a switchable magnetization direction. A reference layer has a fixed magnetization direction. A barrier layer is provided between the free layer and the reference layer. The free layer includes a perpendicularity-maintaining layer and a high-polarizability magnetic layer. The perpendicularity-maintaining layer, if in contact with the barrier layer, has a first surface roughness. The high-polarizability magnetic layer, if in contact with the barrier layer, has a second surface roughness. If the first surface roughness is smaller than the second surface roughness, the perpendicularity-maintaining layer is in contact with the barrier layer. If the second surface roughness is smaller than the first surface roughness, the high-polarizability magnetic layer is in contact with the barrier layer.

According to an exemplary embodiment of the present inventive concept, a magnetoresistive memory includes a magnetic tunnel junction device and an electrode which applies a voltage to the magnetic tunnel junction device. The magnetic tunnel junction device is provided as follows. A free layer has a switchable magnetization direction. A reference layer has a fixed magnetization direction. A barrier layer is provided between the free layer and the reference layer. The free layer includes a perpendicularity-maintaining layer and a high-polarizability magnetic layer. The perpendicularity-maintaining layer, if in contact with the barrier layer, has a first surface roughness. The high-polarizability magnetic layer, if in contact with the barrier layer, has a second surface roughness. If the first surface roughness is smaller than the second surface roughness, the perpendicularity-maintaining layer is in contact with the barrier layer. If the second surface roughness is smaller than the first surface roughness, the high-polarizability magnetic layer is in contact with the barrier layer.

According to an exemplary embodiment of the present inventive concept, a magnetic tunnel junction device is provided as follows. A free layer has a switchable magnetization direction with a first layer and a second layer. A reference layer has a fixed magnetization direction. A barrier layer is provided between the free layer and the reference layer. The first layer of the free layer is in contact with the barrier layer and disposed between the barrier layer and the second layer of the free layer. The first layer has a smaller surface roughness compared to if the second layer is in contact with the barrier layer.

### BRIEF DESCRIPTION OF DRAWINGS

These and other features of the present inventive concept will become more apparent by describing in detail exemplary embodiments thereof with reference to the accompanying drawings of which:

FIG. 1 is a cross-sectional view of a magnetic tunnel junction device according to an exemplary embodiment of the present inventive concept;

FIG. 2 illustrates an epitaxial relationship among a substrate, a buffer layer, a high-polarizability magnetic layer, and a perpendicularity-maintaining layer according to an exemplary embodiment of the present inventive concept;

FIG. 3 illustrates the relationship between the thickness of a high-polarizability magnetic layer and its magnetic property according to an exemplary embodiment of the present inventive concept;

FIG. 4 illustrates the relationship between the thickness of a high-polarizability magnetic layer and its magnetic properties according to an exemplary embodiment of the present inventive concept;

FIG. 5 is an atomic force microscopy (AFM) image showing a surface of a perpendicularity-maintaining layer and a surface of a high-polarizability magnetic layer according to an exemplary embodiment;

FIG. 6 is an atomic force microscopy (AFM) image showing a surface of a perpendicularity-maintaining layer and a surface of a high-polarizability magnetic layer formed as a comparative example;

FIG. 7 displays x-ray diffraction patterns for a sample according to an exemplary embodiment of the present inventive concept;

FIG. 8 is a cross-sectional view of a magnetic tunnel junction device according to an exemplary embodiment of the present inventive concept;

FIG. 9 is a schematic view illustrating the relationship between a perpendicularity-maintaining layer, a magnetic coupling control layer, and a high-polarizability magnetic layer according to an exemplary embodiment of the present inventive concept;

FIG. 10 illustrates the magnetic properties of a magnetic tunnel junction device having a magnetic coupling control layer with a thickness of about 2 nm according to an exemplary embodiment of the present inventive concept;

FIG. 11 is a perspective view illustrating a magnetoresistive memory according to an exemplary embodiment; and

FIG. 12 is a cross-sectional view of a magnetic tunnel junction device according to an exemplary embodiment of the present inventive concept.

### DETAILED DESCRIPTION OF EXEMPLARY EMBODIMENTS

Exemplary embodiments of the inventive concept will be described below in detail with reference to the accompanying drawings. However, the inventive concept may be embodied in different forms and should not be construed as limited to the embodiments set forth herein. In the drawings, the thickness of layers and regions may be exaggerated for clarity. Like reference numerals may refer to the like elements throughout the specification and drawings.

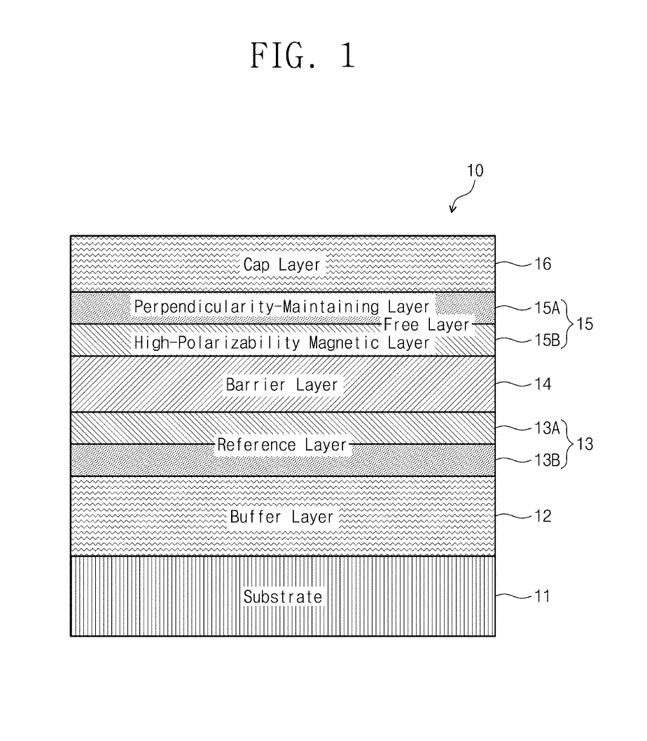

FIG. 1 is a cross-sectional view of a magnetic tunnel junction device according to an exemplary embodiment. In FIG. 1, a magnetic tunnel junction device 10 is provided with a substrate 11, a buffer layer 12, a reference layer 13, a barrier layer 14, a free layer 15, and a cap layer 16.

The substrate 11 is a silicon (Si) substrate. For example, the substrate 11 may be a thermal oxide film-attached Si substrate or a Si single crystal substrate.

The buffer layer 12 may be a stabilization layer formed on the substrate 11. For example, the buffer layer 12 may be in contact with the substrate 11. The buffer layer 12 may be a layer which includes chromium (Cr), tantalum (Ta), silver (Au), tungsten (W), platinum (Pt), or titanium (Ti).

The reference layer 13 may be formed of a Heusler alloy film 13A and a Co/Pt multilayer film 13B. The Heusler alloy film 13A may be a layer composed of a cobalt (Co)-based full-Heusler alloy. For example, the Co-based full-Heusler alloy may be Co₂FeSi, Co₂MnSi, Co₂FeMnSi, Co₂FeAl, or Co₂CrAl. The Co/Pt multilayer film 13B may be provided to impart a large perpendicular magnetic anisotropy. As illustrated in FIG. 1, the Heusler alloy film 13A may be in contact with the barrier layer 14, and the Co/Pt multilayer film 13B may be in contact with the buffer layer 12. The reference layer 13 is also called a fixed layer.

The barrier layer 14 may be a layer including an insulating material. The barrier layer 14 may include at least one of magnesium oxide (MgO), titanium oxide (TiO), aluminum oxide (AlO), magnesium-zinc oxide (MgZnO), magnesium-boron oxide (MgBO), titanium nitride (TiN), and vanadium nitride (VN). The barrier layer 14 may be interposed between the reference layer 13 and the free layer 15.

If a voltage perpendicular to the interface between the reference layer 13 and the free layer 15 is applied, a current may flow in the magnetic tunnel junction device 10 via the tunneling effect through the barrier layer 14.

The free layer 15 may include a perpendicularity-maintaining layer 15A and a high-polarizability magnetic layer 15B. The order in which the perpendicularity-maintaining layer 15A and the high-polarizability magnetic layer 15B are stacked is as described below. The free layer 15 is also called the write layer.

Among the perpendicularity-maintaining layer 15A and the high-polarizability magnetic layer 15B, a layer having a smaller surface roughness when stacked on the barrier layer 14 may be stacked on the barrier layer 14, and the other layer having a greater surface roughness when stacked on the barrier layer 14 may be stacked on the layer having the smaller surface roughness.

For example, the perpendicularity-maintaining layer 15A, if in contact with the barrier layer 14, has a first surface roughness and the high-polarizability magnetic layer 15B, if in contact with the barrier layer 14, has a second surface roughness. If the second surface roughness is smaller than the first surface roughness, the high-polarizability magnetic layer 15B is in contact with the barrier layer 14, as shown in FIG. 1. If the first surface roughness is smaller than the second surface roughness, the perpendicularity-maintaining layer 15A is in contact with the barrier layer 14, unlike FIG. 1.

According to an exemplary embodiment of the present inventive concept, the free layer 15 may have a first layer and a second layer. The first layer of the free layer 15 is in contact with the barrier layer 14 and disposed between the barrier layer and the second layer of the free layer 15. The first layer has a smaller surface roughness compared to if the second layer is in contact with the barrier layer 14.

The term “lattice strain” of a layer of material refers to strain of the crystal lattice in directions at least substantially parallel to the plane of the layer of material.

For example, the lattice strain (6) of the Heusler alloy film 13A, in the case of deformation from a cubic lattice (space group (Fm-3m)) to a tetragonal lattice (space group (14/mm)), may be defined as follows:

δ=(a−ao)/ao

Here, ao is the lattice constant in the three axes of the cubic lattice (that is, ax=ay=az=a0), and a is the lattice constant in the two axes of the tetragonal lattice (that is, ax=ay, az=c).

A positive value of δ corresponds to a tensile strain, and a negative value of δ corresponds to a compressive strain.

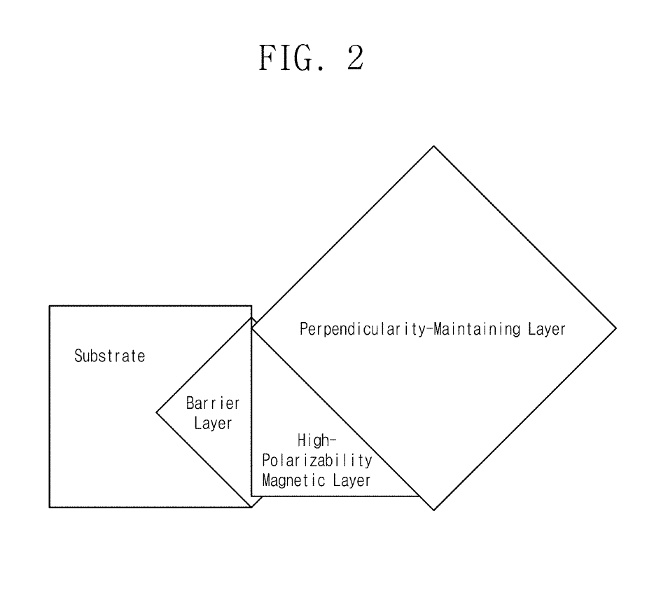

FIG. 2 illustrates the lattice strain in the case of epitaxial growth. Specifically, FIG. 2 illustrates the size relationships and epitaxial relationships between the respective crystal lattice constants of the substrate, the barrier layer, the high-polarizability magnetic layer, and the perpendicularity-maintaining layer. It is assumed for the convenience of a description that the perpendicular-maintaining layer 15A is formed of a manganese (Mn)-based alloy; the high-polarizability magnetic layer 15B is formed of a CFS (Co₂FeSi); and the barrier layer 14 is formed of MgO. When the crystal lattice of the manganese (Mn)-based alloy is compared with the crystal lattice of CFS (Co₂FeSi) or the crystal lattice of MgO, the lattice strain (δ) may be considered in an epitaxial relationship matching a 45° rotation on the x-y plane. For example, to calculate the lattice strain (δ), it is assumed that a lattice matching between the perpendicular-maintaining layer 15A, the high-polarizability magnetic layer 15B and the barrier layer 14 is formed as shown in FIG. 2. In this way, the lattice strain (δ) is calculated as in the case of the cubic crystal. For example, after the lattice constant difference between the barrier layer 14 and the perpendicularity-maintaining layer 15A is compared with the lattice constant difference between the barrier layer 14 and the high-polarizability magnetic layer 15B, a layer having a smaller lattice strain among the perpendicularity-maintaining layer 15A and the high-polarizability magnetic layer 15B is stacked on the barrier layer 14, and the other layer having a greater lattice strain is stacked on the layer having the smaller lattice strain. For example, the layer having the smaller lattice strain (δ) among the perpendicularity-maintaining layer 15A and the high-polarizability magnetic layer 15B is in contact with the barrier layer 14, and the other layer having the greater lattice strain (δ) is in contact with the layer having the smaller lattice strain so that the layer having the smaller lattice strain (δ) is interposed between the barrier layer 14 and the other layer.

By adopting such a stacking structure, and thereby reducing the lattice strain between the barrier layer 14, and the perpendicularity-maintaining layer 15A or high-polarizability magnetic layer 15B in the free layer 15, the surface roughness may be reduced, and a stronger magnetic coupling may be achieved between the perpendicularity-maintaining layer 15A and the high-polarizability magnetic layer 15B. Consequently, the magnetization direction of the free layer 15 may be perpendicular to the stacking surface.

The stacking structure of the free layer 15 in FIG. 1 is that the high-polarizability magnetic layer 15B, when in contact with the barrier layer 14, has a smaller lattice strain compared to if the perpendicularity-maintaining layer 15A is in contact with the barrier layer 14.

For example, the perpendicularity-maintaining layer 15A, if in contact with the barrier layer 14, has a first lattice strain; the high-polarizability magnetic layer 15B, if in contact with the barrier layer, has a second lattice strain; if the first lattice strain is smaller than the second lattice strain, the perpendicularity-maintaining layer 15A is in contact with the barrier layer 14; and if the second lattice strain is smaller than the first lattice strain, the high-polarizability magnetic layer 15B is in contact with the barrier layer 14.

The perpendicularity-maintaining layer 15A may be a layer that keeps the magnetic field direction aligned with the easy axis of magnetization. The perpendicularity-maintaining layer 15A may be a layer including a Mn-based alloy having a L1₀ structure or a D0₂₂ structure. For example, the perpendicularity-maintaining layer 15A may be a layer including MnGe, MnGa, or MnAl having a L1₀ structure or a D0₂₂ structure.

The high-polarizability magnetic layer 15B may be a layer having high spin polarizability. The high-polarizability magnetic layer 15B may be a layer including a Heusler alloy film having a L2₁ structure or a B2 structure. In an exemplary embodiment, the high-polarizability magnetic layer 15B may be a layer including a Co-based full-Heusler alloy. For example, the Co-based full-Heusler alloy may be Co₂FeSi, Co₂MnSi, Co₂FeMnSi, Co₂FeAl, or Co₂CrAl.

The cap layer 16 may be a stabilization layer formed on the free layer 15. For example, the cap layer 16 may be a layer including ruthenium (Ru) or tantalum (Ta).

Next, description will be given of the lattice strain between the barrier layer 14 and the perpendicularity-maintaining layer 15A, and the lattice strain between the barrier layer 14 and the high-polarizability magnetic layer 15B. Table 1 displays the changes in the lattice constants of metals included in the perpendicularity-maintaining layer 15A or high-polarizability magnetic layer 15B and metals included in the barrier layer 14. In Table 1, the lattice strain is a value (percent) obtained by dividing a value, obtained by subtracting the lattice constant of a metal included in the barrier layer 14 from the lattice constant of a metal included in the perpendicularity-maintaining layer 15A or the high-polarizability magnetic layer, by the lattice constant of the perpendicularity-maintaining layer 15A or the high-polarizability magnetic layer 15B.

TABLE 1

| | | MgO | MgAl₂O₄-based |
|---|---|---|---|
| | Lattice constant (nm) | 0.421 | 0.396-0.404 |
| bcc-Fe | 0.2866 | −3.80% | 0.3-2.5% |
| L2₁-Co₂FeSi | 0.564 | −5.30% | −1.4-+0.8% |
| L1₀-FePt | 0.385 | −8.60% | −4.8-−2.7% |
| D0₂₂-MnGa | 0.390 | −7.40% | −3.4-−1.4% |
| GaAs | 0.565 | −5.10% | −1.2-+1.1% |

The combinations in Table 1 are merely exemplary, and other combinations are possible. Below, lattice constants are displayed for materials which may be used in the barrier layer 14, the perpendicularity-maintaining layer 15A, and the high-polarizability magnetic layer 15B. Table 2 displays lattice constants of alloys which may be used in the high-polarizability magnetic layer 15B.

TABLE 2

| | | Curie temperature | Lattice constant |
|---|---|---|---|
| Alloy | Crystal structure | [K] | [nm] |
| Co₂MnSi | Cubic (L2₁ | 985 | 0.565 |
| | Cu₂MnAl type) | | |
| Co₂FeSi | Cubic (L2₁ | 1100 | 0.566 |
| | Cu₂MnAl type) | | |
| Co₂FeAl | Cubic (L2₁ | 1170 | 0.573 |
| | Cu₂MnAl type) | | |
| Co₂CrAl | Cubic (L2₁ | 334 | 0.574 |
| | Cu₂MnAl type) | | |

Table 3 displays lattice constants of alloys which may be used in the perpendicularity-maintaining layer 15A.

TABLE 3

| Alloy | Lattice constant [nm] |
|---|---|
| D0₂₂-MnGa | 0.390 |
| D0₂₂-MnGe | 0.382 |
| L10-MnAl | 0.395 |

Table 4 displays lattice constants of alloys which may be used in the barrier layer 14. In Table 4, the value for Cr, used in an experiment for an exemplary embodiment of the inventive concept, is shown.

TABLE 4

| | Lattice constant [nm] |
|---|---|
| MgO | 0.421 (0.595) |
| MgAl₂O₄ | 0.571 |
| Cr | 0.411 (0.581) |

Next, description will be given of how the stacking order of the barrier layer 14, the perpendicularity-maintaining layer 15A, and the high-polarizability magnetic layer 15B affects the magnetic properties of the magnetic tunnel junction device 10.

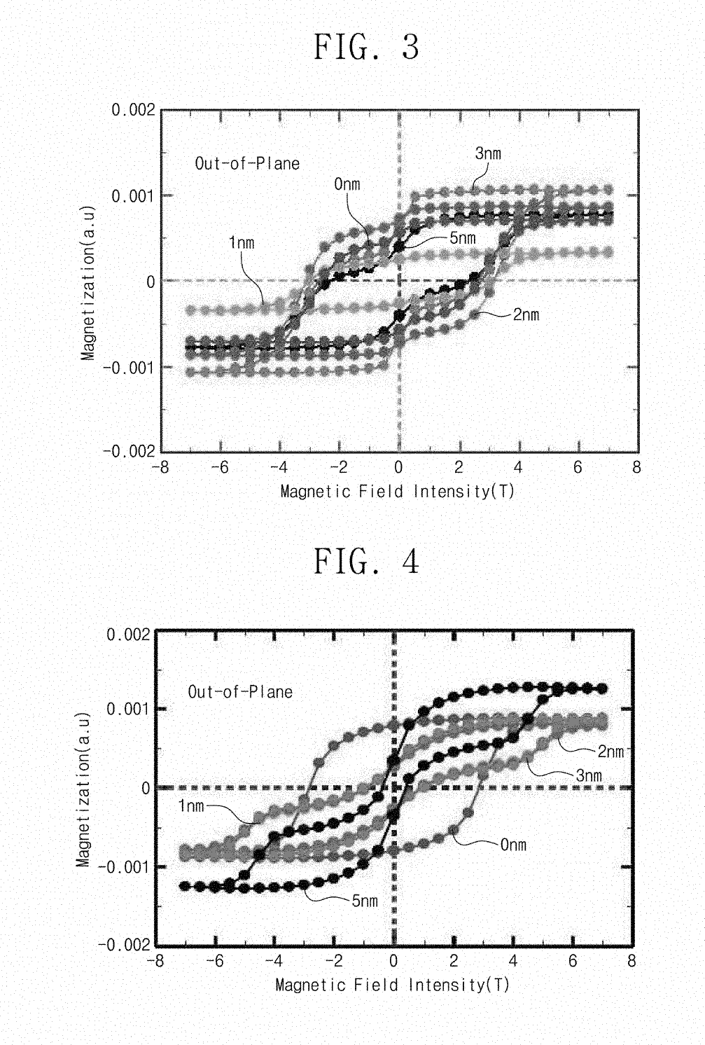

In FIG. 1, the magnetic tunnel junction device 10 may be formed by using a sputter method by sequentially depositing the buffer layer 12 (for example, a Cr layer), the reference layer 13, the barrier layer 14, the free layer 15, and the cap layer 16 on the substrate 11. FIGS. 3 and 4 illustrate the magnetic properties of a sample formed according to an exemplary embodiment of the present inventive concept. The formation method may involve using a sputter method to form, in order, the buffer layer 12 (for example, Cr layer), the high-polarizability magnetic layer 15B (for example, a CFS layer), and the perpendicularity-maintaining layer 15A (for example, a Mn alloy layer) on the substrate 11.

The relationship between a magnetic field intensity and a magnetic property of a free layer, which is part of the magnetic tunnel junction device, is measured using a vibrating sample magnetometer (VSM). In VSM, a magnetic field is applied up to 70 kOe (7 T) in a direction perpendicular to a film surface of the free layer.

FIG. 3 illustrates the relationship between the thickness of a high-polarizability magnetic layer and its magnetic property. In FIG. 3, the horizontal axis represents the magnetic field intensity of a magnetic field applied to the high-polarizability magnetic layer in the VSM. The vertical axis represents a degree of magnetization of the high-polarizability magnetic layer caused by the magnetic field applied thereto. In FIG. 3, to analyze the magnetic property of the free layer 15 in the magnetic tunnel junction device 10, in which the barrier layer 14 includes MgO, the perpendicularity-maintaining layer 15A includes MnGa, and the high-polarizability magnetic layer 15B includes Co₂FeMnSi, a sample includes those layers stacked in accordance with an exemplary embodiment of the inventive concept to have a reduced surface roughness. The thickness of the high-polarizability magnetic layer in the sample has been changed. Hereinafter, the same reference numerals of FIG. 1 will be used to indicate a layer of the sample.

As illustrated in FIG. 3, magnetization is strongly coupled between the perpendicularity-maintaining layer 15A and the high-polarizability magnetic layer 15B. In FIG. 3 if the film thickness of the high-polarizability magnetic layer 15B is less than about 3 nm, the magnetization of the Co-based full-Heusler alloy layer (the high-polarizability magnetic layer 15B) may have out-of-plane magnetic anisotropy in a single layer to be perpendicularly oriented with respect to a surface of the Co-based full-Heusler alloy layer. The interfacial roughness between the perpendicularity-maintaining layer 15A and high-polarizability magnetic layer 15B in the free layer 15 has about 0.5 nm.

For comparison, an example is described below in which, in order to examine the effect of surface roughness, the film formation order of the perpendicularity-maintaining layer 15A and the high-polarizability magnetic layer 15B is reversed. FIG. 4 illustrates the relationship between the thickness of a high-polarizability magnetic layer and magnetic properties. In FIG. 4, the horizontal axis represents a magnetic field intensity, and the vertical axis represents a degree of magnetization. In FIG. 4, the magnetization of the Co-based full-Heusler alloy layer (the high-polarizability magnetic layer 15B) may have in-plane magnetic anisotropy oriented in parallel to a surface of the Co-based full-Heusler alloy layer. The interfacial roughness between the perpendicularity-maintaining layer 15A and the high-polarizability magnetic layer 15B in the FIG. 4 is about 1-2 nm.

Next, an atomic force microscopy (AFM) analysis is performed to evaluate an interfacial roughness between the perpendicularity-maintaining layer 15A and the high-polarizability magnetic layer 15B of the free layer 15.

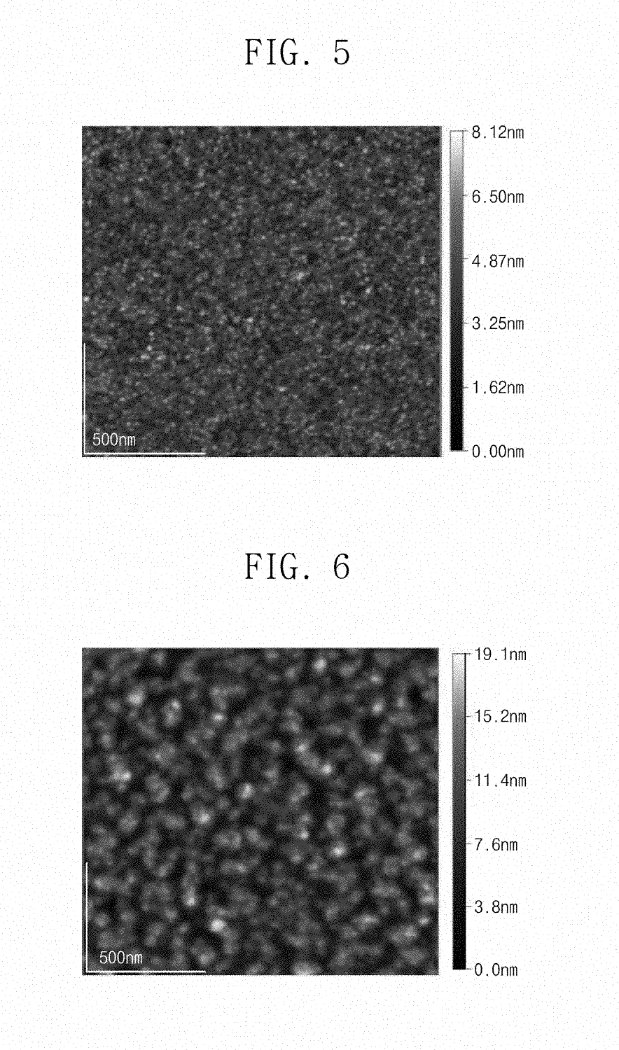

FIG. 5 is an atomic force microscopy (AFM) image of a surface after the formation of a perpendicularity-maintaining layer and a high-polarizability magnetic layer formed such that a lattice strain is reduced. In addition, FIG. 6 is an AFM image of a surface after the formation of a perpendicularity-maintaining layer and a high-polarizability magnetic layer formed such that a lattice strain is increased. For example, FIG. 5 illustrates an AFM image of the surface of the high-polarizability magnetic layer that is formed on the barrier layer to infer the interfacial roughness between the perpendicularity-maintaining layer and the high-polarizability magnetic layer. For example, the high-polarizability magnetic layer is in contact with the barrier layer. In addition, FIG. 6 illustrates an AFM image of the surface of the perpendicularity-maintaining layer produced on the barrier layer. For example, the perpendicularity-maintaining layer is in contact with the barrier layer.

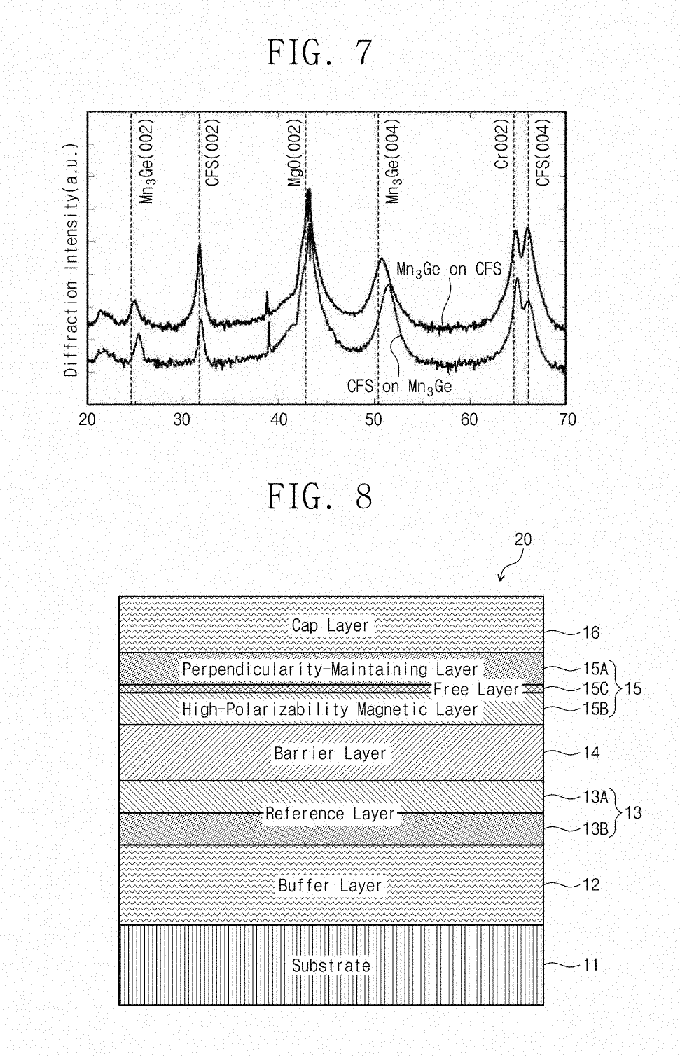

In x-ray analysis of the free layer 15 which is a composite film of the perpendicularity-maintaining layer 15A and the high-polarizability magnetic layer 15B, the lattice strain of an Mn-based alloy film formed on a Co₂FeSi (CFS) alloy layer on a Cr layer is smaller than the Mn-based alloy film which is stacked directly onto the Cr layer. FIG. 7 displays x-ray diffraction patterns for a first sample prepared by forming, in order, a perpendicularity-maintaining layer and a high-polarizability magnetic layer on a Cr layer and a second sample prepared by forming, in order, a high-polarizability magnetic and a perpendicularity-maintaining layer on a Cr layer. In FIG. 7, the vertical axis represents a diffraction intensity, and the horizontal axis represents a diffraction angle. FIG. 7 displays the diffraction intensity for examples in which a barrier layer 14 including a Cr layer, a high-polarizability magnetic layer 15B including a CFS alloy film, a perpendicularity-maintaining layer 15A including a Mn-based alloy film, and a cap layer 16 including Ta are formed. For example, FIG. 7 displays the example in which the order of formation is the CFS alloy film followed by the Mn-based alloy film, and the example in which the order of formation is Mn-based alloy film followed by CFS alloy film. Moreover, by comparing FIGS. 5 and 6, the change in surface roughness may be caused by changing the film formation order. From the results of x-ray analysis and the surface roughness analysis, the surface roughness control of the interface obtained in an exemplary embodiment of the inventive concept is effective for perpendicularly orienting the magnetization of the high-polarizability magnetic layer 15B.

Thus, by reducing the lattice strain between a barrier layer and a perpendicularity-maintaining layer or a high-polarizability magnetic layer in a write layer, a magnetic tunnel junction device may reduce interfacial roughness between the perpendicularity-maintaining layer or the high-polarizability magnetic layer and ensure that a strong magnetic coupling therebetween is achieved so that the magnetization of the high-polarizability magnetic layer is perpendicularly oriented. The magnetic tunnel junction device of FIG. 1 may have an enhanced thermal stability.

Hereinafter, an example is described in which a magnetic coupling control layer is provided between a perpendicularity-maintaining layer and a high-polarizability magnetic layer in a write layer.

FIG. 8 is a cross-sectional view of a magnetic tunnel junction device according to an exemplary embodiment. In FIG. 8, the magnetic tunnel junction device 20 may include a substrate 11, a buffer layer 12, a reference layer 13, a barrier layer 14, a free layer 15, and a cap layer 16. The free layer 15 may be provided with a perpendicularity-maintaining layer 15A, a high-polarizability magnetic layer 15B, and a magnetic coupling control layer 15C.

The magnetic coupling control layer 15C may be stacked between the perpendicularity-maintaining layer 15A and the high-polarizability magnetic layer 15B. For example, the magnetic coupling control layer 15C may be a nonmagnetic film including a Cr alloy. The present inventive concept is not limited thereto. For example, the magnetic coupling control layer 15C may include a Pt film or a W film.

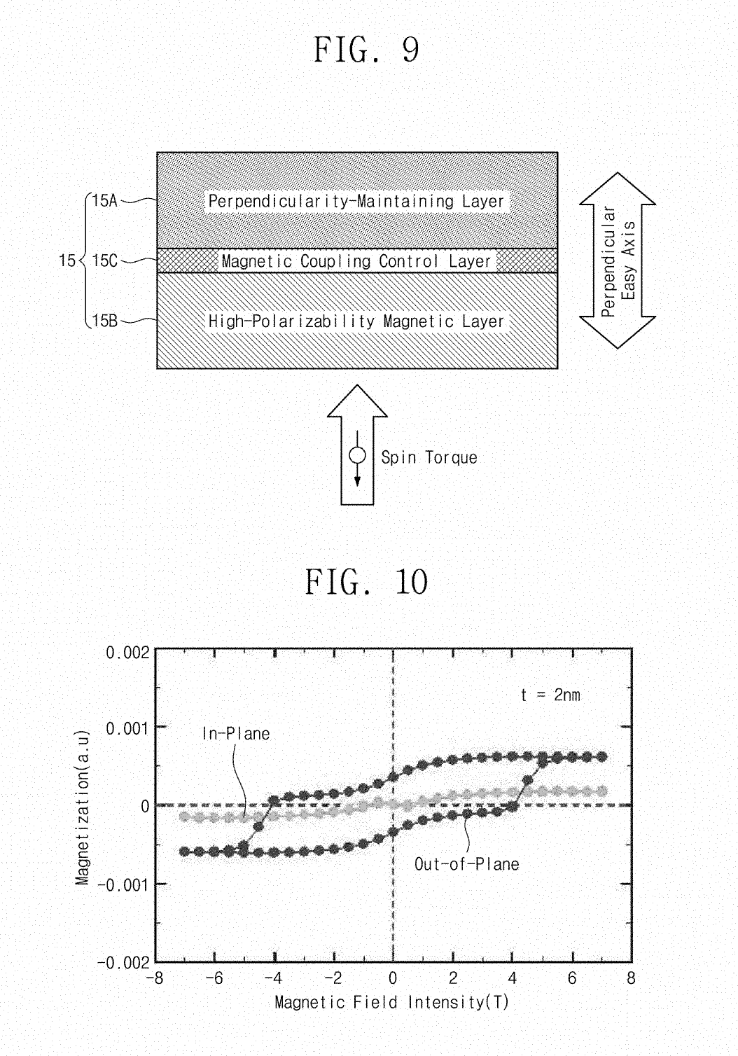

FIG. 9 is a schematic view illustrating the structure and magnetic relationship of an insulating layer and a perpendicularity-maintaining layer, a magnetic coupling control layer, and a high-polarizability magnetic layer in a write layer. As illustrated in FIG. 9, although the perpendicularity-maintaining layer 15A keeps the magnetization direction aligned with the easy axis of magnetization, due to the presence of the magnetic coupling control layer 15C between the perpendicularity-maintaining layer 15A and the high-polarizability magnetic layer 15B, the coupling of the perpendicularity-maintaining layer 15A and the high-polarizability magnetic layer 15B with the magnetization direction is weakened, and it becomes easier to change the magnetization direction of the high-polarizability magnetic layer 15B using less current compared to the magnetic tunnel junction device 10 of FIG. 1.

FIG. 10 illustrates the magnetic properties of the magnetic tunnel junction device 20 having a magnetic coupling control layer with a thickness of about 2 nm. In FIG. 10, the magnetic coupling control layer 15C having a thickness of about 2 nm may be interposed between the perpendicularity-maintaining layer 15A and the high-polarizability magnetic layer 15B. As illustrated in FIG. 10, the magnetic coupling of the perpendicularity-maintaining layer 15A and the high-polarizability magnetic layer 15B is being degraded.

Thus, the magnetic tunnel junction device 20 of FIG. 8 may achieve a high-speed magnetoresistive random-access memory (MRAM), compared to a magnetic tunnel junction device including a magnetic coupling control layer between a barrier layer and a perpendicularity-maintaining layer or between the barrier layer and a high-polarizability magnetic layer, may be thermally more stable, and may perform a write operation at a lower current.

The magnetic coupling control layer 15C may achieve thermal stability and perform a write operation at a low current at the thickness of about 1 nm or below. For example, the magnetic coupling control layer 15C may have a thickness of about 0.3 nm to 0.7 nm.

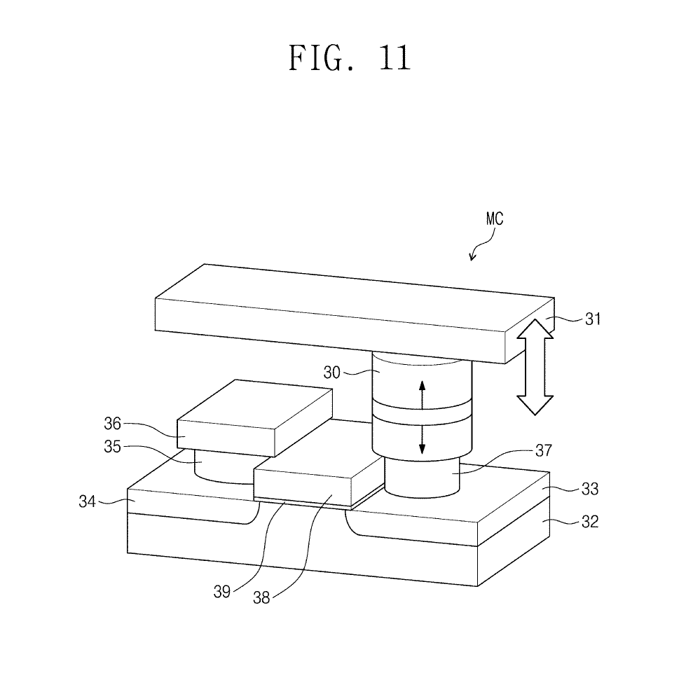

FIG. 11 is a perspective view illustrating the main parts of an exemplary magnetoresistive memory according to an exemplary embodiment of the present inventive concept.

In FIG. 11, a magnetoresistive memory cell MC may include a magnetic tunnel junction device 30, a bit line 31, a first contact plug 35, a second contact plug 37, and a word line 38.

The magnetoresistive memory cell MC may further include a semiconductor substrate 32, a first diffusion region 33, a second diffusion region 34, and a source line 36, a gate insulating film 39. The magnetic tunnel junction device 30 of FIG. 11 may correspond to the magnetic tunnel junction device 10 of FIG. 1. The present inventive concept is not limited thereto. For example, the magnetic tunnel junction device 30 of FIG. 11 may correspond to the magnetic tunnel junction device 20 of FIG. 8.

The magnetoresistive memory may be formed by arranging the magnetoresistive memory cell MC in plural in the form of a matrix. With multiple bit lines and word lines, the magnetoresistive memory cell MC in plural is connected to each other. The magnetoresistive memory cell MC may use a spin transfer torque method to perform a write operation of data.

The semiconductor substrate 32 includes the first diffusion region 33 and the second diffusion region 34 on the top face. The first diffusion region 33 may be spaced apart at a predetermined distance from the second diffusion region 34. The first diffusion region 33 may function as a drain region, and the second diffusion region 34 may function as a source region. The first diffusion region 33 may be connected to the magnetic tunnel junction device 30 through the second contact plug 37 disposed therebetween.

The bit line 31 may be disposed above the semiconductor substrate 32, and be also connected to the magnetic tunnel junction device 10. The bit line 31 may be connected to a write circuit (not shown) and a read circuit (not shown).

The second diffusion region 34 may be connected to the source line 36 through the first contact plug 35 disposed therebetween. The source line 36 may be connected to the write circuit (not shown) and the read circuit (not shown).

The word line 38 may be disposed on the semiconductor substrate 32, with the gate insulating film 39 disposed therebetween, such that the word line 38 may be adjacent to the first diffusion region 33 and the second diffusion region 34. The word line 38 and the gate insulating film 39 may function as a selection transistor. By receiving a current from a circuit, which is not shown, the word line 38 may turn on the selection transistor.

In the magnetoresistive memory, the bit line 31 and the first diffusion region 33 may apply a voltage, as electrodes, to the magnetic tunnel junction device 10, and the spin torque of electrons, which are aligned in a predetermined direction due to application of the voltage, changes the magnetization direction of free layer 15. In addition, by changing the current direction, the data values written to the magnetoresistive memory may be changed.

Thus, by reducing the lattice strain between a barrier layer, and a perpendicularity-maintaining layer or a high-polarizability magnetic layer in the free layer, the magnetoresistive memory cell MC of FIG. 11 may reduce an interfacial roughness and ensure that strong magnetic coupling is achieved between the perpendicularity-maintaining layer and the high-polarizability magnetic layer, and thus may perpendicularly orient the magnetization of the high-polarizability magnetic layer. In addition, the magnetoresistive memory cell MC of FIG. 11 may have increased thermal stability.

The inventive concept is not limited thereto. For example, the magnetic tunnel junction device 20 of FIG. 8 may be applicable to the magnetoresistive memory cell MC of FIG. 11.

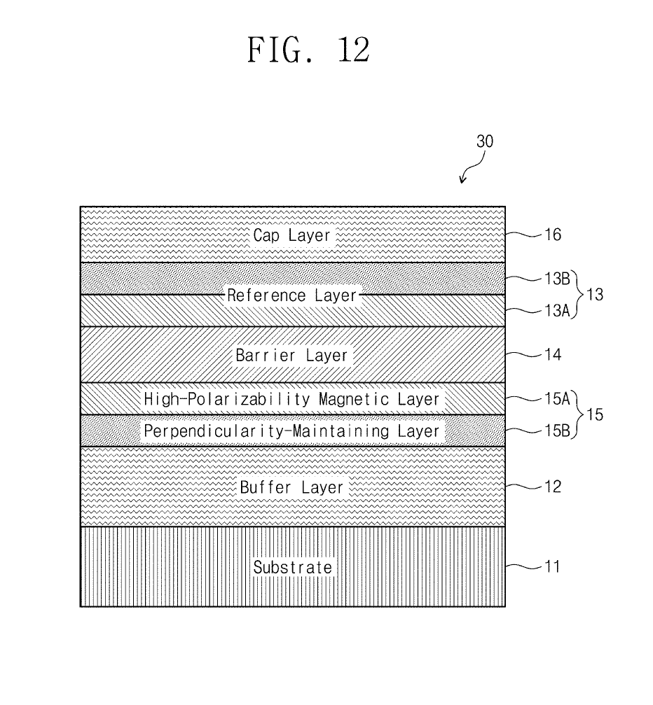

FIG. 12 is a cross-sectional view of a magnetic tunnel junction device according to an exemplary embodiment. In FIG. 12, the magnetic tunnel junction device 10 of FIG. 11 may include a substrate 11, a buffer layer 12, a free layer 15, a barrier layer 14, a reference layer 13, and a cap layer 16 that are stacked in the listed order. According to an exemplary embodiment, a perpendicularity-maintaining material having even less lattice strain on the buffer layer 12 may be selected.

Furthermore, a Mn alloy layer may include three or more types of metals.

While the present inventive concept has been shown and described with reference to exemplary embodiments thereof, it will be apparent to those of ordinary skill in the art that various changes in form and detail may be made therein without departing from the spirit and scope of the inventive concept as defined by the following claims.

What is claimed is:

1. A magnetic tunnel junction device comprising:
a free layer having a switchable magnetization direction;
a reference layer having a fixed magnetization direction; and
a barrier layer provided between the free layer and the reference layer,
wherein the free layer includes a perpendicularity-maintaining layer and a high-polarizability magnetic layer,
wherein the perpendicularity-maintaining layer, if in contact with the barrier layer, has a first surface roughness, and
wherein the high-polarizability magnetic layer, if in contact with the barrier layer, has a second surface roughness,
wherein if the first surface roughness is smaller than the second surface roughness, the perpendicularity-maintaining layer is in contact with the barrier layer, and
wherein if the second surface roughness is smaller than the first surface roughness, the high-polarizability magnetic layer is in contact with the barrier layer.

2. The magnetic tunnel junction device of claim 1,
wherein the perpendicularity-maintaining layer, if in contact with the barrier layer, has a first lattice strain, and
wherein the high-polarizability magnetic layer, if in contact with the barrier layer, has a second lattice strain,
wherein if the first lattice strain is smaller than the second lattice strain, the perpendicularity-maintaining layer is in contact with the barrier layer, and
wherein if the second lattice strain is smaller than the first lattice strain, the high-polarizability magnetic layer is in contact with the barrier layer.

3. The magnetic tunnel junction device of claim 1,
wherein the perpendicularity-maintaining layer includes a manganese (Mn)-based alloy having a L1₀ structure or a D0₂₂ structure.

4. The magnetic tunnel junction device of claim 3,
wherein the perpendicularity-maintaining layer includes a Mn-germanium (Ge) alloy, a Mn-gallium (Ga) alloy, or a Mn-aluminum (Al) alloy.

5. The magnetic tunnel junction device of claim 1,
wherein the high-polarizability magnetic layer includes a Heusler alloy having a L2₁ structure or a B2 structure.

6. The magnetic tunnel junction device of claim 5,
wherein the high-polarizability magnetic layer includes Co₂FeSi, Co₂MnSi, Co₂FeMnSi, Co₂FeAl, or Co₂CrAl.

7. The magnetic tunnel junction device of claim 1,
wherein the free layer further includes a magnetic coupling control layer disposed between the perpendicularity-maintaining layer and the high-polarizability magnetic layer, and
wherein the magnetic coupling control layer has a thickness of about 1 nm or smaller.

8. The magnetic tunnel junction device of claim 1,
wherein an interfacial roughness between the perpendicularity-maintaining layer and the high-polarizability magnetic layer in the free layer is less than about 0.7 nm.

9. A magnetoresistive memory comprising a magnetic tunnel junction device and an electrode which applies a voltage to the magnetic tunnel junction device, the magnetic tunnel junction device including:
a free layer having a switchable magnetization direction;
a reference layer having a fixed magnetization direction; and
a barrier layer provided between the free layer and the reference layer,
wherein the free layer includes a perpendicularity-maintaining layer and a high-polarizability magnetic layer, and
wherein the perpendicularity-maintaining layer, if in contact with the barrier layer, has a first surface roughness,
wherein the high-polarizability magnetic layer, if in contact with the barrier layer, has a second surface roughness,
wherein if the first surface roughness is smaller than the second surface roughness, the perpendicularity-maintaining layer is in contact with the barrier layer, and
wherein if the second surface roughness is smaller than the first surface roughness, the high-polarizability magnetic layer is in contact with the barrier layer.

10. A magnetic tunnel junction device comprising:
a free layer having a switchable magnetization direction and including a first layer and a second layer;
a reference layer having a fixed magnetization direction; and
a barrier layer provided between the free layer and the reference layer,
wherein the first layer of the free layer is in contact with the barrier layer and disposed between the barrier layer and the second layer of the free layer,
wherein the first layer has a smaller surface roughness compared to if the second layer is in contact with the barrier layer.

11. The magnetic tunnel junction device of claim 10,
wherein an interfacial roughness between the first layer and the second layer in the free layer is less than about 0.7 nm.

12. The magnetic tunnel junction device of claim 10,
wherein the first layer is a high-polarizability magnetic layer,
wherein the second layer is a perpendicularity-maintaining layer.

13. The magnetic tunnel junction device of claim 12,
wherein the high-polarizability magnetic layer is formed of a Heusler alloy including Co₂FeSi, Co₂MnSi, Co₂FeMnSi, Co₂FeAl, or Co₂CrAl.

14. The magnetic tunnel junction device of claim 12,
wherein the perpendicularity-maintaining layer includes a Mn-based alloy including a Mn-germanium (Ge) alloy, a Mn-gallium (Ga) alloy, or a Mn-aluminum (Al) alloy.

15. The magnetic tunnel junction device of claim 10,
wherein the free layer further includes a magnetic coupling control layer disposed between the first layer and the second layer, and
wherein the magnetic coupling control layer has a thickness of about 1 nm or smaller.
